(19) United States
(12) Patent Application Publication
(10) Pub. No.: US 2014/0092565 A1
(43) Pub. Date: Apr. 3, 2014

(54) OPTICAL MODULE WITH AN ELECTRONIC CONNECTOR ALIGNED WITH A SUBSTRATE AND A METHOD TO ASSEMBLE THE SAME

(71) Applicant: Sumitomo Electric Industries, Ltd., Osaka-shi (JP)

(72) Inventors: Tateki NAKASHIMA, Yokohama-shi (JP); Hiromi Nakanishi, Yokohama-shi (JP)

(73) Assignee: Sumitomo Electric Industries, Ltd., Osaka-shi (JP)

(21) Appl. No.: 14/029,290

(22) Filed: Sep. 17, 2013

(30) Foreign Application Priority Data
Oct. 1, 2012 (JP) 2012-219429

(51) Int. Cl. H05K 7/02; H05K 13/04

(52) U.S. Cl. CPC H05K 7/02; H05K 13/0465
USPC 361/748; 228/180.22

(57) ABSTRACT

An optical module having a substrate and an electrical connector whose terminals are precisely aligned with pads on the substrate is disclosed. The electrical connector provides upper and lower terminals, while, the substrate provides upper and lower pads each having a V-shaped cut opened for a direction along which the upper and lower terminals are slide. As the electrical connector is assembled with the substrate, the terminals slide along the edge of the V-shaped cut and slide onto the pads at the bottom of the V-shaped cut, which automatically and precisely aligns the terminals with the pads.

### BACKGROUND OF THE INVENTION

1. Field of the Invention

The present application relates to an optical module and a method of assemble the optical module.

2. Background Arts

A conventional optical module provides an optical receptacle to be mated with an external optical connector secured in an end of an optical fiber. Mating the optical connector with the optical receptacle, an optical active device installed within the optical module may optically couple with the optical fiber. However, the optical coupling between the optical connector and the optical receptacle generally requires precise alignment, which inevitably increases a price of the optical module and/or the optical connector.

An optical communication system with small or medium numbers of coupling nodes, for instance, an intercity communication and/or a metro-access system, may install such nodes showing reliable and qualified optical coupling. However, a communication between apparatuses and equipment within a datacenter has a short reach, which eases the condition of the coupling quality, but needs a huge number of nodes. Accordingly, the conventional optical module with the optical receptacle mated with the optical connector brings an excess performance.

A new concept, what is called an active optical cable (hereafter denoted as AOC), has been proposed in the field. The AOC is attached in a tip end of an optical fiber and installs an optical-to-electrical transducer, typically, a semiconductor laser diode (hereafter denoted as LD) and/or a semiconductor photodiode (hereafter denoted as PD). In an AOC, an optical fiber is permanently fixed to, for instance, a housing of the AOC after the optical alignment against the transducer is performed. The AOC converts an optical signal transmitted within the optical fiber into an electrical signal and outputs thus converted electrical signal to a host system through an electrical connector. A Japanese Patent Application published as JP-2012-032574A has disclosed one type of such AOCs. Because the electrical connect or a coupling through an electrical connector does not request a precise alignment between a connector and a plug, which drastically reduces not only a price of the component itself but a cost to assemble the optical module. Moreover, because the transmission distance between nodes in the data center is far shorter, typically several hundred meters at most, the signal quality to be transmitted in optical and electrical forms practically causes no degradation.

A continuous and eager request to make electronic and/or optical apparatus compact has been expanded in the field of the AOC. However, a small-sized electronic connector inevitably accompanies with narrowing a pitch of leads in the connector, which requests a precise control of the alignment between the leads and pads. In particular, when the electrical connector is a type of the double sided connector, further preciseness of the alignment is necessary.

### SUMMARY OF THE INVENTION

An aspect of the present application relates to an arrangement of an optical module that comprises a substrate and an electronic connector assembled with the substrate. The substrate includes a top surface and a back surface. The top surface provides a plurality of first pads, while, the back surface provides a plurality of second pads. The electronic connector has a plurality of first leads and a plurality of second leads. Each of the first leads and each of the second leads extend along a direction, specifically, a longitudinal direction connecting the substrate to the electronic connector. A feature of the optical module according to an embodiment is that each of the first pads includes a cut opened for the direction and having a left oblique edge and a right oblique edge with a space perpendicular to the direction gradually narrowing along the direction.

The cut typically has a V-shape. When the electronic connector is assembled with the substrate, the first leads of the electronic connector are guided along the V-shaped cut, which automatically and precisely aligns the first leads with the first pads. Even the pitch of the first leads, or the first pads becomes narrower, typically less than 0.6 mm, the misalignment between the first leads and the first pads are effectively prevented.

Another aspect according to an embodiment of the present invention relates to a method to assemble an optical module that provides optical components permanently aligned with optical fibers, electronic components, a substrate that mounts the optical components and the electrical components thereon, and an electronic connector assembled with the substrate. The electronic connector provides a plurality of first leads and a plurality of second leads, while, the substrate provides a plurality of first pads connected to the first leads in the top surface and a plurality of second pads connected to the second leads in the back surface. The method according to an embodiment includes steps of: forming a first solder on the first pads; inserting the substrate into a space between the first leads and the second leads of the electronic connector such that the first leads slide onto the first solder on the first pads; and forming a second solder on the second pads in the back surface of the substrate. A feature of the process is that each of the first pads provides a cut opened for an insertion direction of the substrate, and the cut provides a left oblique edge and a right oblique edge with a space therebetween narrowing along the insertion direction, where each of the first leads is automatically aligned by the cut at the insertion of the substrate.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 shows an outer appearance of an active optical cable (AOC) with an optical module according to an embodiment of the invention;

FIG. 2 is an exploded view of on optical module shown in FIG. 1;

FIG. 3 shows a cross section taken along the line appeared in FIG. 2;

FIG. 4A is a plan view magnifying a portion IV appeared in FIG. 2, FIG. 4B further magnifies a rear end of a pad with a V-shaped cut, and FIG. 4C shows an alteration of the cut with a trapezoidal shape;

FIG. 5 is a flowchart to assemble the optical module shown in FIG. 2;

FIGS. 6A to 6C show processes to assemble the optical module viewed from a top;

FIGS. 7A to 7C show processes corresponding to the processes shown in FIGS. 6A to 6C, respectively, but viewed from a back;

FIGS. 8A to 8C show processes subsequent to the process shown in FIGS. 6C and 7C;

FIGS. 9A to 9C show processes subsequent to the process shown in FIG. 8C;

FIG. 10 is a flow chart of a process to assemble the electronic connector with the substrate according to an embodiment of the invention;

FIGS. 11A and 11B show an example of misalignment between the leads of the electrical connector and the pads on the substrate according to a conventional arrangement;

FIGS. 12A and 12B show an exemplary result of alignment between the leads and the pads according to an embodiment of the present invention; and

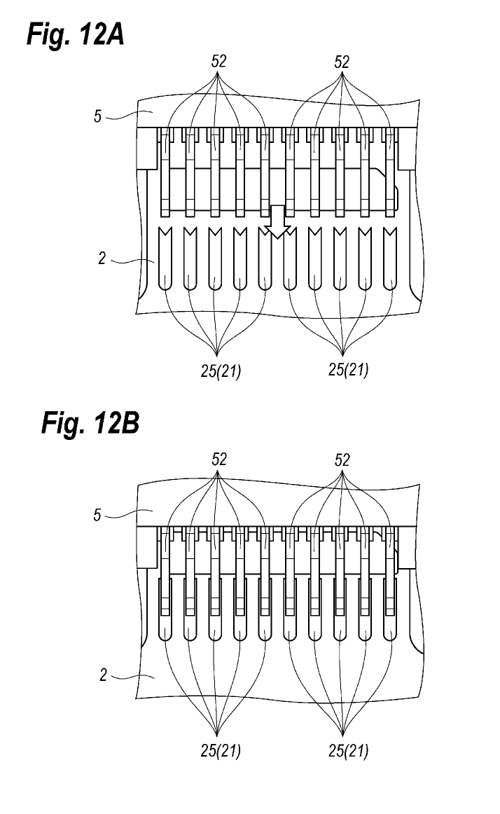

FIG. 13 is a flow chart of a process to assemble the electronic connector with the substrate according to a sequence modified from those shown in FIG. 10.

### DESCRIPTION OF EMBODIMENTS

Next, some embodiments according to the present application will be described as referring to accompany drawings. In the description of the drawings, elements same with or similar to each other will be referred by numerals or symbols same with or similar to each other without overlapping explanations.

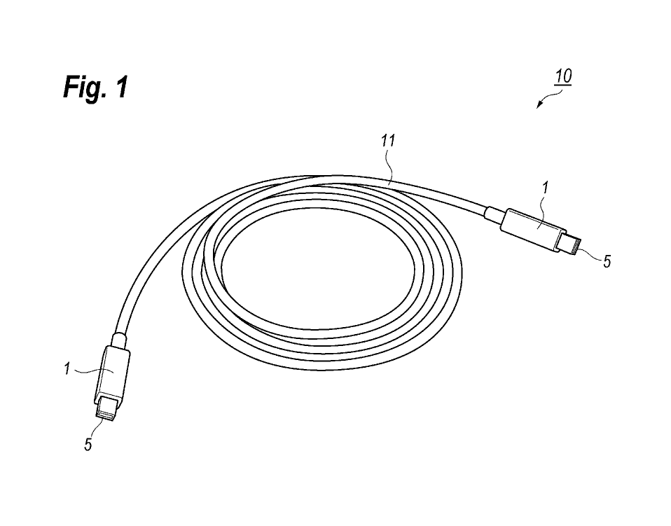

FIG. 1 roughly shows an outer appearance of an AOC with an optical module according to an embodiment of the present application. The AOC 10 shown in FIG. 1, which follows one of standards called as “Thunderbolt”, includes two optical modules 1 and an optical cable 11 connecting the optical modules 1. The optical cable 11 typically includes a plurality of optical fibers bundled in a single cable. The optical modules 1, which are installed in respective ends of the optical cable 11, electrically couple with, for instance, external apparatuses. One of the optical modules 1 converts electrical signals provided from the external apparatus coupled thereto into optical signals, and transmits thus converted optical signals to the other optical module 1. The other optical module 1 converts thus transmitted optical signals into electrical signals and provides thus converted electrical signals to the other external apparatus coupled thereto.

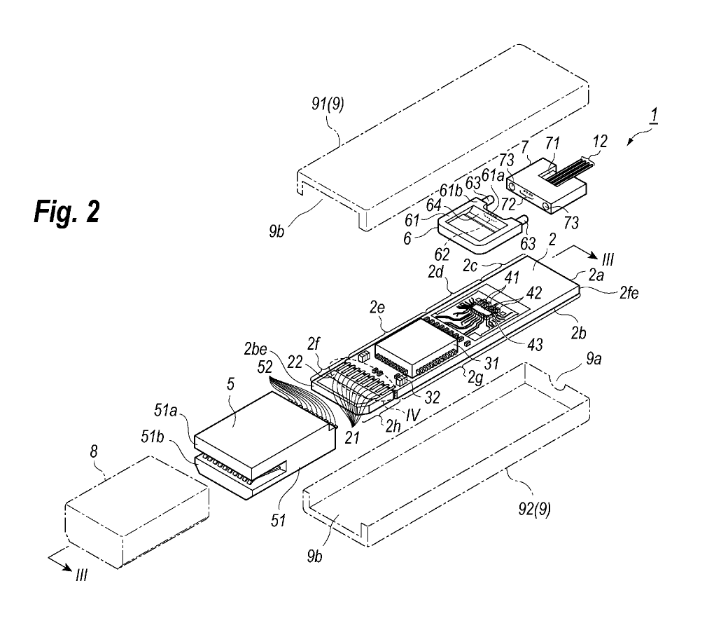

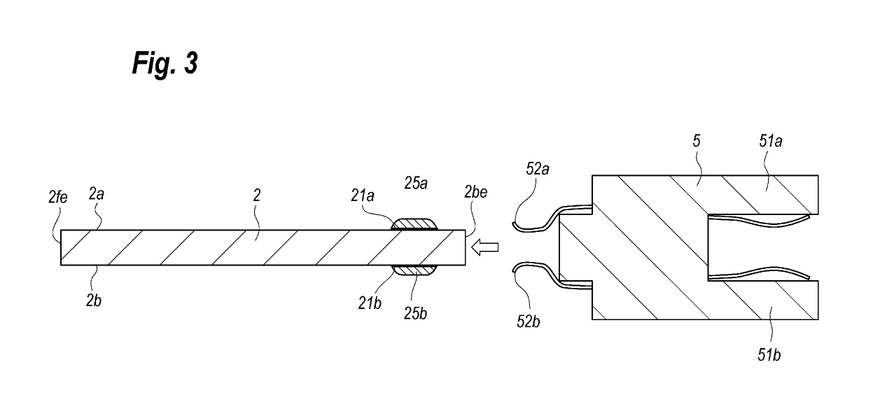

FIG. 2 is an exploded view of the optical module 1 shown in FIG. 1; and FIG. 3 is a cross section taken along the line III-III appeared in FIG. 2. The optical module 1 includes a substrate 2, electrical components 3, optical components 4, an electrical connector 5, a coupling component 6, an optical ferrule 7, an electrical shell 8, and a housing 9.

The substrate 2, which has a rectangular plane shape, is a type of a printed circuit board with a width less than 11 mm and a length less than 38 mm, where dimensions of the circuit board are determined by the standard of the optical module. The circuit board 2 includes top and back surfaces, 2a and 2b, to mount electrical components 3 and optical components 4 thereon. The top surface 2a is divided into four areas, 2c to 2f, arranged along the longitudinal direction connecting the front end 2fe to the rear and 2be. In the description below presented, directions of the front, the rear, the top, and the back, are introduced only for the explanation sake, and they do not restrict the scope of the invention. The first to fourth areas, 2c to 2f, mount the optical ferrule 7, the coupling component 6, the electrical components 3, and the electrical connector 5, respectively. The second area 2d provides pads 24 to mount the optical components 4 thereon; and the third area 2f also provides pads 23a to mount the electrical components 3 thereon. The fourth area 2f provides the first pads 21a. These pads, 21a, 23a, and 24, provided in second to fourth areas, 2d to 2f, are formed by electrically conductive metal sheet.

The back surface 2b includes fifth and sixth areas, 2g and 2h, respectively, where two areas, 2g and 2h, are arranged in this order along the longitudinal direction connecting the front end 2fe to the rear end 2be of the substrate 2. The fifth area 2g provides pads 23b to mount the electrical components 3 thereon. The sixth area 2h provides the second pads 21b to mount the electrical connector 5. These pads, 21b and 23b, which will be described in detail later, are made of electrically conductive metal sheet. Moreover, the sixth area 2h in the back surface 2b of the substrate 2 is opposite to the fourth area 2f in the top surface 2a.

The electrical components 3 perform preset sequences for electrical signals converted by the optical components, and output thus processed electrical signals external to the optical module 1 through the electrical connector 5. The electrical components 3 perform another preset sequences for electrical signals provided from an external of the optical module through the electrical connector 5, and provide thus processed electrical signals to the optical components 4. The electrical components 3, which include an integrated circuit (IC) 31, capacitors 32, and so on, are mounted in the second area 2d in the top surface 2a and the fifth area 2g in the back surface 2b. The IC 31 is a type of, for instance, ASIC (application specific integrated circuit) implemented with functions of an optical transmitter and an optical receiver. The embodiment shown in FIG. 2 does not provide any discrete components. All functions for the optical transmitter and the optical receiver are implemented within the IC 31.

The optical components 4, which includes an electrical-to-optical transducer 41 (hereafter denoted as E/O device), an optical-to-electrical transducer 42 (hereafter denoted as O/E device), and an IC 43 to driver the E/O device 41 and the O/E device 42, is mounted in the third area 2d of the top surface 2a. The E/O device 41 converts the electrical signals into optical signals and outputs thus converted optical signals to the optical fiber through the coupling component 6. The E/O device may include, for instance, vertical cavity surface emitting laser diodes (VCSELs), where each of the VCSELs corresponds to an optical channel. The O/E device 42, which converts optical signals provided from the optical fiber 12 through the coupling component 6 into electrical signals, may be a plurality of PDs each corresponding to one optical channel. The E/O device 41 and the O/E device 42 of the present embodiment each has an optically active surface facing upward, namely, normal to the top surface of the substrate 2. The embodiment shown in FIG. 2 includes two E/O devices 41 and two O/E devices 42 each integrating a plurality of devices.

The IC 43 includes drivers to drive the E/O devices 41 based on electrical signals provided from the electronic components 3 and pre-amplifiers to amplify electrical signals converted from the optical signals and to provide thus amplified electrical signals to the electronic components 3. The AOC 10 generally implements with a plurality of transmitter channels and a plurality of receiver channels; accordingly, the IC 43 installs a plurality of drivers each corresponding to respective transmitter channels and a plurality of pre-amplifiers each corresponding to respective receiver channels. That is, the IC 43 has an arrayed architecture for both of the optical transmitter and the optical receiver.

The electrical connector 5, which is attached to the rear end 2be of the substrate 2, includes a body 51 and a plurality of leads 52. The body 51, which is made of resin or plastic, includes an upper body 51a and a lower body 51b in a rear thereof. The leads 52, which are made of metal pin, extend longitudinally to pierce the body 51. The leads 52 have a width of about 0.2 mm along the lateral direction of the module.

The leads 52 includes a plurality of first leads 52a and a plurality of second leads 52b. The first leads 52a extend along an inner bottom surface of the upper body 51a, pierces the body 51, and extrudes frontward from the body 51; while, the second leads 52b extend along an inner top surface of the lower body 51b, pierces the body 51 and protrudes frontward from the body 51. The first leads 52a in the rear end thereof are warped to protrude toward the lower body 51b, and in the front end thereof are also warped toward the second lead 52b. The second leads 52b in the rear end thereof are warped toward the upper body 51a, and in the front part thereof are also warped toward the first lead 52a. Although not clearly shown in figures, the present embodiment provides ten (10) pairs of the first lead 52a and the second lead 52b. Each of the first leads 52a, or the second leads 52b, makes a pitch to the next lead of 0.6 mm at most. The first lead 52a and the second lead 52b set a space therebetween at each front ends substantially equal to a thickness of the substrate 2.

The coupling component 6 is a member to couple the optical fiber 12 secured in the ferrule 7 optically with the E/O devices 41 and/or the O/E devices 42 mounted on the substrate 2. Specifically, the coupling component 6 is mounted on the second area 2d to cover the optical components 4. The coupling component 6, which is made of resin in the present embodiment, includes a body 61, guide pins 63, and a mirror 64. The body 61, which has a box shape with a center hollow, includes a front wall 61a with two thicker portions 61b in respective sides of the front wall 51a. The guide pins 63 are secured to respective thicker portions 61b and extrude frontward therefrom. The front wall 61a also includes holes 72 corresponding to and facing bores 72 for the optical fibers 12. The mirror 64 is provided in a rear surface of the front wall 61a. The mirror 64 makes an angle of 45° against the top surface 2a of the substrate 2, and a reflecting surface of the mirror faces frontward and downward.

The ferrule 7, which is a type of mechanically transferable (hereafter denoted as MT) in the present embodiment, aligns a plurality of optical fibers 12. The ferrule 7 with a box shape is made of resin and attached to an end of the optical fibers 12. The ferrule 7 provides a depression 71 to support the optical fibers 12 therein, bores 72 each receiving the optical fiber independently, and guide holes 73 formed in both sides of the ferrule 7. Inserting the guide pins 63 into respective guide holes 73, the optical fibers 12 may be optically coupled with the E/O devices 41 and the O/E devices 42 collectively. Light output from the optical fiber 12, which is inserted into the bore of the ferrule 7, passes the bore 72, is reflected by 90° by the mirror 64 toward the substrate 2, and enters the 0/E device 42 mounted on the substrate 2. Or, light output from the E/O device 41 mounted on the substrate 2 upward is reflected by 90° by the mirror 64 toward the ferrule 7, passes the bore 72, and enters the optical fiber 12. The optical fibers 12 constitute the optical cable 11 shown in FIG. 1 collectively covered by a sheath.

The shell 8, which is made of metal, covers and electrically shields the electrical connector 5, in particular, the leads 52 of the electrical connector 5. The shell 8 has dimensions of about 7.4 mm width and about 4.5 mm length. While, the housing 9 of the optical module 1, which may be made of resin with a box shape, has dimensions of about 38 mm longitudinally, about 10.8 mm laterally, and about 7.9 mm in height. The housing 9, which may include an upper housing 91 and a lower housing 92, provides an opening 9a in the front end thereof, while another opening 9b in the rear end. The housing 9 encloses the substrate 2, the electronic components 3, the optical components 4, the coupling component 6, and the ferrule 7. The electrical connector 5 and the shell 8 extend from the latter opening 9b, while, the optical cable 11 is pulled out from the other opening 9a.

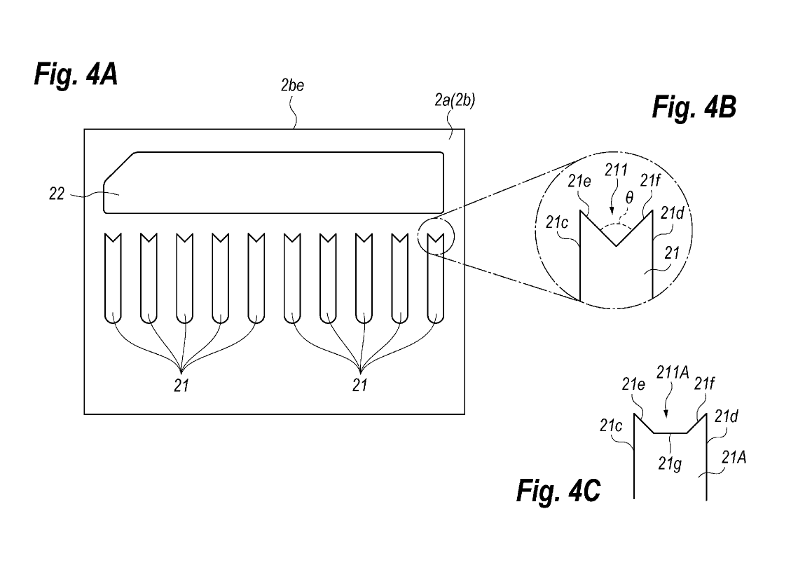

The fourth area 2f in the top surface 2a of the substrate 2 and the sixth are 2h in the back surface 2b thereof will be described in detail. As shown in FIG. 4, which magnifies the fourth area 2f, the fourth area 2f provides a plurality of first pads 21a each having a length less than 1.8 mm along the longitudinal direction and a width less than 0.3 mm but greater than a width of the leads 52. The first pad 21a has a thickness of about 3 μm. Each of the first pads 21a is arranged in an array with a pitch less than 0.6 mm to the next pad 21a. The embodiment shown in FIG. 4 provides ten (10) first pads 21a.

The sixth area 2h has a configuration substantially same with those of the fourth area 4f; that is, the sixth area 2h also provides a plurality of second pads 21b each having a shape substantially same with those of the first pads 21a. The second pads 21b are laterally arranged by a pitch less than 0.6 mm. The embodiment shown in FIG. 4 provides ten (10) seconds pads 21b. The specification below refers to the first and second pads, 21a and 21b, as a pad 21 when two types of pads, 21a and 21b, are unnecessary to be distinguished.

Each of the pads 21 includes a left edge 21c and a right edge 21d both extending longitudinally. Rear end of each of the pads 21 provides a cut 211 cut from the rear end of the left 21c and that of the right 21d forwardly. The cut 211 provides a left oblique edge 21e and a right oblique edge 21f. The left oblique edge 21e extends from the left edge 21c toward a center of the pad 21, while, the right oblique edge 21f extends from the right edge 21d toward the center. Because of the V-shape of the cut 211, a lateral space between the left oblique edge 21e and the right oblique edge 21f gradually narrows from the rear end thereof toward the deep end of the cut 211. The left oblique edge 21e and the right oblique edge 21f become substantially symmetry with respect to a longitudinal center of the pad 21, and make an angle of θ. That is, the cut 211 is a V-shaped cut with an angle of θ, where the angle θ may be, for instance, 90°.

The pad 21 is covered by solder 25 with a shape substantially tracing the shape of the pad 21 and a preset thickness. The solder 25 on a rear end of the pad 21 forms a guide that enables to guide terminals 52 inserted from the rear end 2be of the substrate 2. The embodiment shown in FIG. 4 further provides a ground pattern (hereafter denoted as GND pattern) 22 between the rear end of the pad 21 and the end 2be of the substrate 2. The GND pattern 22, which lowers impedance of the leads 52 attached to the pads 21, may be covered with a resist.

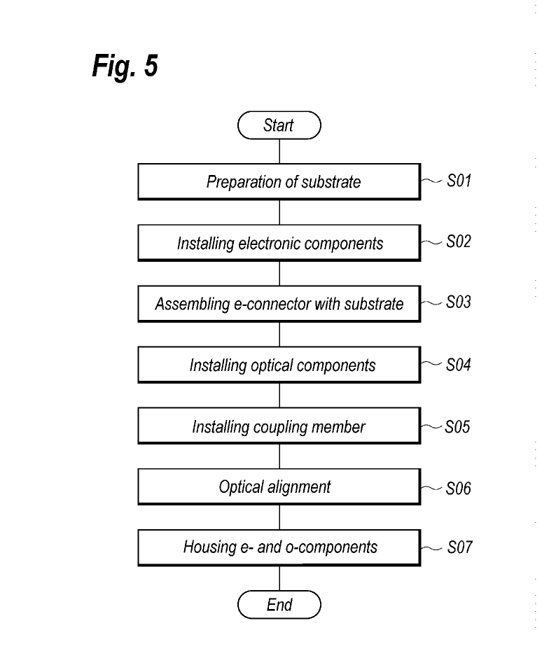

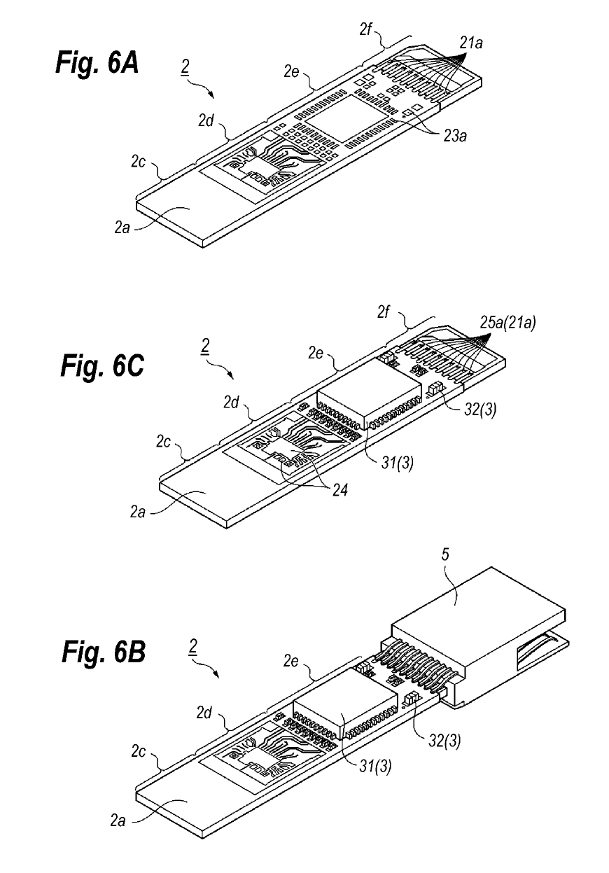

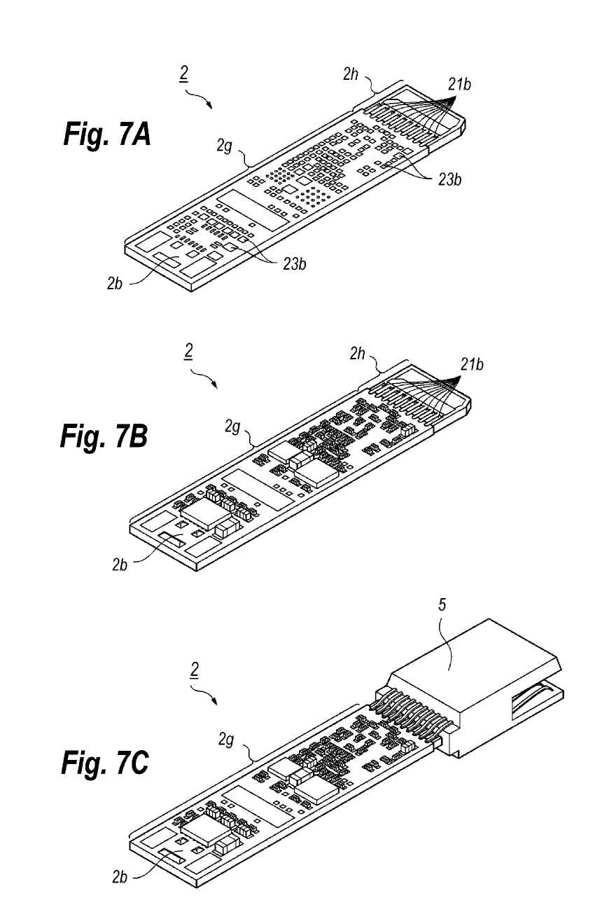

Next, a process to assemble the optical module 1 will be described. FIG. 5 is a flow chart of the process; while, FIGS. 6 to 9 show processes to assemble the optical module 1, where FIGS. 6A to 6B show processes from a side of the top surface 2a of substrate 2, while, FIGS. 7A to 7B show processes from a side of the back surface 2b of substrate 2. The process roughly comprises a preparation of the substrate S01, an installation of the electrical components S02, an installation of the electrical connector S03, an installation of the optical connector S05, an installation of the coupling component S06, and the installation of the housing S07.

The preparation of the substrate S01, as shown in FIGS. 6A and 7A, prepares the substrate 2. The substrate 2 may be a type of glass epoxy laminate board with interconnections and pads thereof beforehand by conventional techniques. The process S02, as shown in FIGS. 6B and 7B, installs electrical components 3 on the pads 23a in the third area 2e of the top surface 2a and on the pads 23b in the fifth area 2g of the back surface 2b of the substrate 2. Then, the reflow soldering glues the electrical components 3 to respective pads, 22a and 23b.

Then, the process S03, as shown in FIGS. 6C and 7C, installs the electrical connector 5 on the substrate 2 by inserting the electrical connector 5 from the rear end 2be of the substrate 2 as putting the substrate 2 by the leads, 52a and 52b. Then, the process solders the second leads 52b to the second pads 21b in the sixth area 2g of the back surface 2b of the substrate 2 and the first leads 52a to the first pad 21a in the fourth area 2f of the top surface 2a of the substrate 2. Thus, the leads, 52a and 52b, are electrically connected to the pads 21. Further details of the process S03 will be described later.

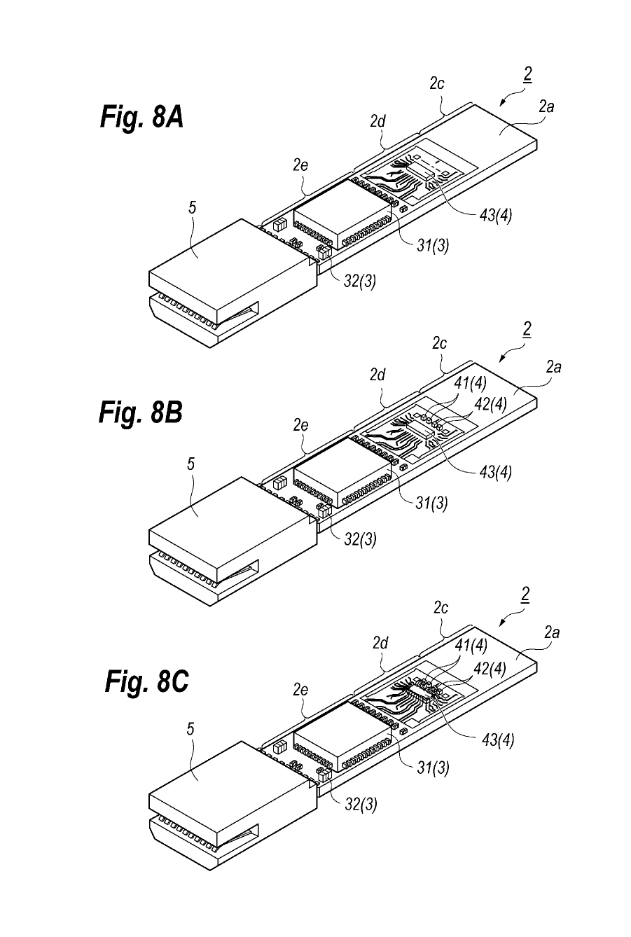

The process S04, as shown in FIG. 8A, further installs the IC 43 on the pads 24 provided in the second area 2d of the top surface 2a; and solders the IC 43 thereon. Moreover, as shown in FIG. 8B, the E/O devices 41 and the O/E devices 42 are soldered on the pad 24 also provided in the second area 2d. The soldering of these devices, 41 and 42, uses a eutectic alloy with relatively lower melting temperature, for instance, gold tin (AuSn) solder. Then, as shown in FIG. 8C, the wire bonding is carried out between the E/O device 41 and the IC 43, between the O/E device 42 and the IC 43, and between the IC 43 and the interconnections provided in the second area 2d.

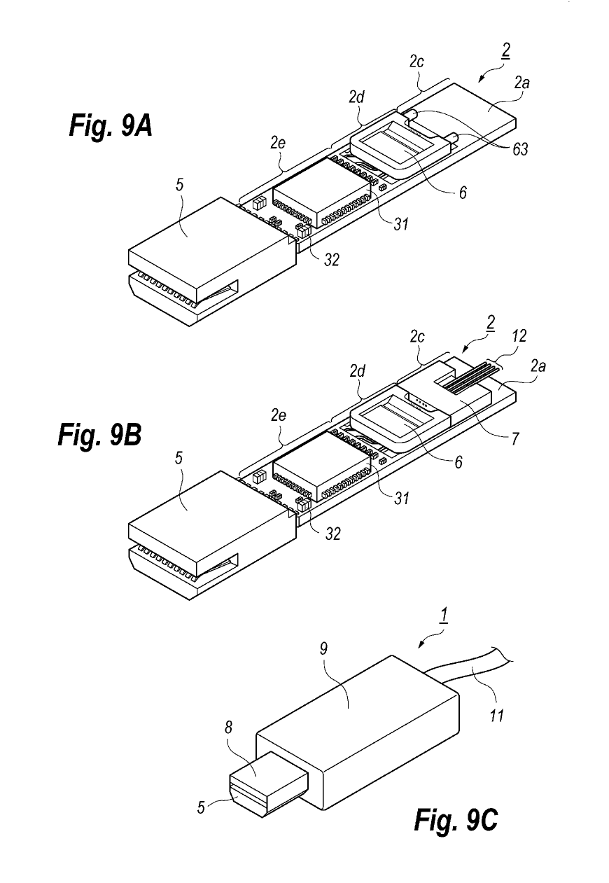

Then, the process S05 installs the coupling component 6 in the second area 2d of the top surface 2a, as shown in FIG. 9A. The coupling component 6 is aligned with the E/O device 41 and the O/E device 42 such that the mirror 64 covers and overlaps the devices, 41 and 42. The next process S06, as shown in FIG. 9B, installs the ferrule 7 assembled with the optical fiber 12 in the optical cable 11 in the first area 2c of the top surface 2a of the substrate 2 such that the guide holes 73 of the ferrule 7 receive the guide pins 63 of the coupling component 6.

The process S07, as shown in FIG. 9C, next assembles the shell 8 to surround the electrical connector 5. The shell 8 protrudes from the opening 9b of the housing 9, while the optical cable 11 is pulled out from the other opening 9b. Thus, the optical module 1 is completed.

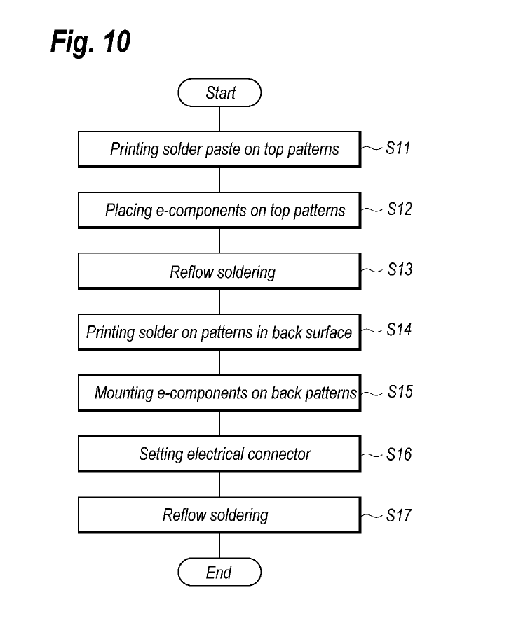

FIG. 10 shows a flow chart to install the electrical components 3 and the electrical connector 5. First, solder pastes are printed on the pads, 21 and 23, in the top surface 2a of the substrate 2 at step S11 using a conventional technique of, for instance, a metal mask. The solder pastes printed thereon has a thickness of about 70 μm. Then, the electronic components 3 are placed on the pads 23a in the third area 2e at step S12. The reflow soldering may melt the solder paste and permanently connect the pads 23a with the electrical components 3 at step S13. Specifically, the reflow furnace sets a temperature to be 260° C. for one minute to melt the solder paste; then, cools down the solder to fix the electrical components 3 with the pads 23a. During the reflow soldering above described, a first solder 25a is formed on the first pad 21a. The first solder 25a has a plane shape substantially tracing the plane shape of the first pad 21a, and a preset thickness. Thus, steps S11 to S13 form the first solder 25a on the first pad 21a.

Subsequently, step S14 prints solder pastes on the pads, 21b and 23b, in the back surface 2b, then, other electrical components 3 are placed on the solder paste on the pads, 21b and 23b. After applying flux on the first solder 25a on the first pad 21a in the top surface 2a, the electrical connector 5 is set on the substrate 2 from the rear end 2be thereof at step S16 such that the first leads 52a slide onto the first pads 21a and the second leads 52b slide onto the second pads 21b. At this process, the V-shaped cut 211 of the pads 21 may guide the leads 52 to align them on a respective center of the pads 21. The first leads 52a are aligned on the first pads 21a and the second leads 52b are aligned on the second pads 21b.

Describing the process further specifically, when the leads 52 of the electrical connector 5 is set forward from the rear end 2be of the substrate 2, the first and second leads, 52a and 52b, in the front warped portions thereof slide on the top and back surfaces, 2a and 2b, because the front warped portions are apart by a space substantially equal to the thickness of the substrate 2, and the end of respective leads, 52a and 52b, reach the end of pads, 21a and 21b. Because the width of the pad 21, namely space between the left oblique edge 21e and the right oblique edge 21f at the rear end of the V-shaped cut 211, is greater than a width of the terminal 52, the tip end of the leads 52 are aligned between two oblique edges, 21e and 21f. As the space between two oblique edges, 21e and 21f, decreases as the leads 52 moves forward, the tip of the leads 52 comes in contact with one of two oblique edges, 21e and 21f. Further sliding the leads forward, a left side of the lead 52 comes in contact with the first solder 25 along the left oblique edge 21e and a right side thereof comes in contact with the first solder 25 along the right oblique edge 21f. Thus, the leads 52, namely, the upper and second leads, 52a and 52b, are adequately positioned on the substrate 2.

Further inserting the substrate 2 between two leads, 52a and 52b, the two leads, 52a and 52b, ride up onto the solder 25. Thus, the leads 52 may be smoothly rid up onto the pads, 21a and 21b, as laterally positioned with respect to respective pads, 21a and 21b; accordingly, the alignment of the leads 52 with respect to the pads 21 of the substrate 2 may be enhanced. Moreover, because the space between two oblique edges, 21e and 21f, at the open end of the pad 21 is wider than the width of the leads 52, the end of the pads 21 is not peeled at the insertion of the leads 52 to the substrate 2.

After the insertion of the leads 52, the reflow soldering not only mounts the electronic components 3 on the back surface 2b but assembles the electrical connector 5 with the substrate 2. Specifically, a temperature condition of 260° C. for 1 minute melts the solder paste on the back surface 2b and the first solder 25a on the first pads 21a and a subsequent process to cool down to a room temperature solidifies the solder to fix the electronic components 3 to the pads 23b and two leads, 52a and 52b, to the first and second pads, 21a and 21b, respectively.

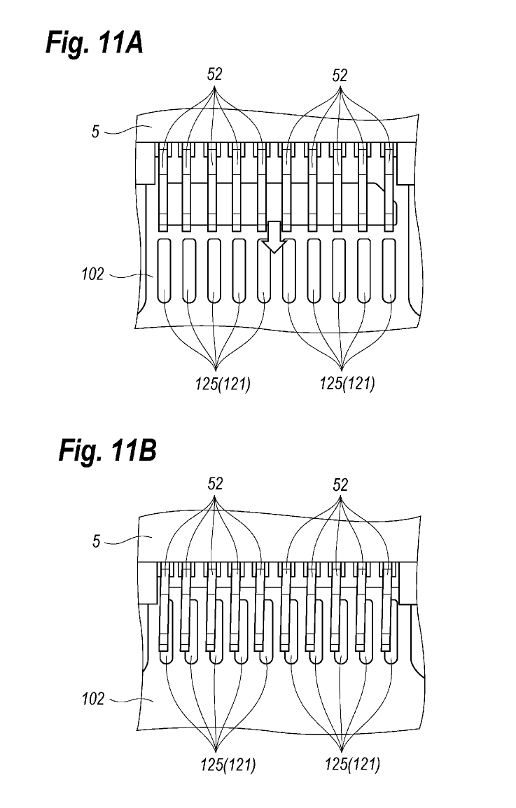

FIGS. 11A and 11B are plan views showing a process to assemble an electrical connector 5 with the substrate 2 that provides pads for the leads 52 but no V-shaped cut of the present embodiment. When the electrical connector 5 is inserted into the substrate 2 as monitoring one of the surfaces, 2a and 2b, of the substrate 102, assuming a case that the top surface 102a is monitored, the first leads 52a are aligned with the pads 121a by a visual inspection of the top surface 102a. However, the other leads, the second leads 52b, are often misaligned with the second pads 102b because the back surface 102b is blinded. Moreover, because the solder on the pad 121 has a substantial thickness, misalignment of the leads 52 with respect to the pads 121 causes the slide of the leads 52 off from the pads 121, which results in a misconnection between the electrical connector 5 and the substrate 2.

On the other hand, the pad 21 of the embodiment provides the V-shaped cut 211 with two oblique edges, 21e and 21f. The first solder 25a applied on the first pad 21a has the plane shape tracing the shape of the first pad 21a and the substantial thickness. Inserting the electrical connector 5 into the substrate 2 from the rear end 2be thereof after the first solder 25a is formed on the first pad 21a; the leads 52 of the electrical connector 5 are automatically positioned by the first solder 25a provided along two oblique edges, 21e and 21f. Because two oblique edges, 21e and 21f, gradually decrease the space therebetween as the tip of the leads 52 is apart from the rear end 2be of the substrate 2; the tip of the leads 52 may slide onto the first solder 25a without peeling the pads 21a. Thus, the lateral position of the leads 52 along the width of the first pads 21a is automatically aligned with respect to the first pads 21a. The present embodiment is able to align the leads 52 of the electrical connector 5 with the first pads 21 on the substrate 2 even one of the surfaces, 2a and 2b, is not inspected.

The pads 21 on the substrate of the present embodiment have the width less than 0.3 mm and the pitch less than 0.6 mm. When the pad 21 provides a rectangular cut, in other words, a U-shaped cut, a width of side patterns putting a space therebetween of the U-shape becomes narrower, which easily causes a peeling-off the pattern from the substrate 2 when the leads 52 scribe edges of the pattern during the insertion. The V-shaped cut of the embodiment leaves a substantial width of the side patterns at positions apart from the edge thereof; accordingly, the tolerance to the peeling-off may be enhanced. Thus, the optical module 1 of the embodiment effectively avoids the misalignment between the terminals 52 of the electrical connector 4 and the pads 21 on the substrate 2.

The optical module and the assembling method thereof are not restricted to embodiments described above. For instance, FIG. 10 is a flow chart of the process where the second reflow soldering is carried out after the electronic components 3 is placed on the back surface 2b of the substrate 2 and the electrical connector 5 is inserted into the substrate 2. The reflow soldering may be divided into two steps. That is, the second reflow soldering is carried out for the electronic components 3 in the back surface 2b of the substrate 2, and an additional reflow soldering is performed only for fixing the electrical connector 5 with the substrate 2.

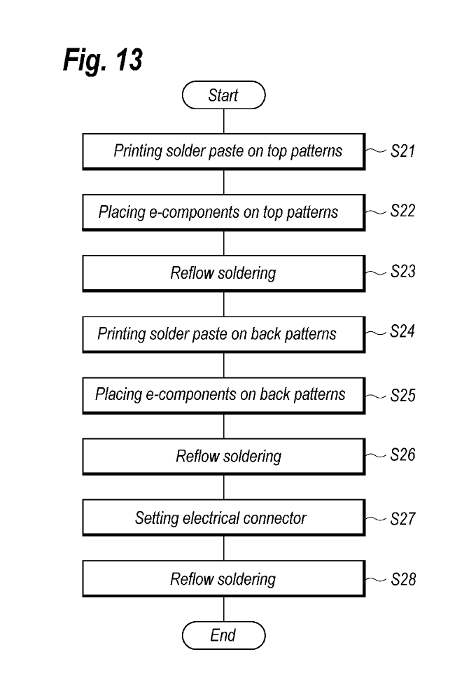

FIG. 13 is a flow chart of another process to assemble the electronic components 3 and the electrical connector 5 with the substrate 2. Processes from S21 to S25 are the same with the processes from S11 to S15. The process shown in FIG. 13 has a feature that the second reflow soldering is carried out at step S26 after mounting the electronic components 3 on the back surface 2b before the electrical connector 5 is set with the substrate 2. Specifically, the second reflow soldering sets a condition of the reflow temperature of 260° C. for one minute. Cooling down the substrate 2, the electronic components 3 are fixed to the pad 23b. During the second reflow soldering, the solder paste applied on the second pad 21b also melts and solidifies, which forms the second solder 25b on the second pads 21b. The second solder 25b has a plane shape thereof tracing the second pads 21b and a substantial thickness. Thus, processes from S24 to S26 forms the second solder 25b on the second pads 21b.

Then, applying fluxes on the first solder 25a on the first pads 21a and the second solder 25b on the second pads 21b, the electrical connector 5 is inserted forward into the substrate 2 from the rear end 2be thereof such that the first leads 52a is placed on the first pads 21a and the second leads 52b is on the second pads 21b. The V-shaped cut of the pads, 21a and 21b, guides the first and second leads, 52a and 52b, and aligns the first and second leads, 52a and 52b, with the pads, 21a and 21b. Subsequent reflow soldering, the third reflow soldering, fixes the electrical connector 5 with the substrate 2 at step S28. The soldering conditions of the temperature of 260° C. for one minute melts the first and second solder, 25a and 25b, each formed on the first and second pads, 21a and 21b, and the subsequent cooling down solidifies the first and second solders, 25a and 25b, to fix the first and second leads, 52a and 52b, to the first and second pads, 21a and 21b.

The embodiments described above provides the V-shaped cut in both of the first and second pads, 21a and 21b, or pads 21 formed on both of the top and back surfaces, 2a and 2b, of the substrate 2. However, another embodiment of the substrate 2, where only one of the pads, 21a and 21b, provide the V-shaped cut and other of the pads, 21b and 21a, provide no V-shaped cut, is applicable. The inspection to check the positional relation between the pads and the terminals is performed for a side of the surfaces, 2a and 2b, where no V-shaped cut is formed in the pads, while, the pads in the other surface, 2b and 2a, automatically position the terminals by the V-shaped cut.

Although the embodiments described above concentrates the pad 21 having the V-shaped cut 211, the pad may have an alteration as shown in FIG. 4C. That is, the pad 21A may have a trapezoidal cut 211A constituted by two slopes, 21e and 21d, and a bottom edge 21g. Even such a cut 211A, the terminals, 52a and 52b, may slide onto the pads, 21a and 21b, as the electrical connector 5 is inserted forward into the substrate 2.

Accordingly, the present invention should not be considered limited to the particular examples described above, but rather should be understood to cover all aspects of the invention as fairly set out in the attached claims. Various modifications, equivalent processes, as well as numerous structures to which the present invention may be applicable will be readily apparent to those of skill in the art to which the present invention is directed upon review of the present specification. The claims are intended to cover such modifications and devices.

What is claimed is:

1. An optical module, comprising:
a substrate having a top surface and a back surface each providing a plurality of first pads and a plurality of second pads thereon, respectively; and
an electronic connector having a plurality of first leads and a plurality of second leads, the first leads and the second leads extending along a direction,
wherein the each of the first pads includes a cut, the cut being opened for the direction and having a left oblique edge and a right oblique edge with a space perpendicular to the direction gradually narrowing along the direction.

2. The optical module of claim 1,
wherein each of the second pads includes the cut.

3. The optical module of claim 2,
wherein the space between two oblique edges is wider than a width of the second leads at respective ends of the second pads.

4. The optical module of claim 1,
wherein the space between the left oblique edge and the right oblique edge is wider than a width of the first leads at respective ends of the first pads.

5. The optical module of claim 1,
wherein each of the cut shapes a V-character.

6. The optical module of claim 1,
wherein each of the cut further provides a bottom connecting the let oblique edge to the right oblique edge, the cut shaping a rectangle.

7. The optical module of claim 1,
wherein the first pads and the second pads are disposed by a pitch less than 0.6 mm.

8. The optical module of claim 1,
wherein the first pads and the second pads each has a width perpendicular to the direction less than 0.3 mm.

9. The optical module of claim 1,
wherein the left oblique edge makes an angle of 90° to the right oblique edge.

10. A method to assemble an optical module with an optical cable, the optical module including a substrate for mounting electronic components and optical components thereon, and an electronic connector having a plurality of first leads and a plurality of second leads, the method comprising steps of:
forming a first solder on a plurality of first pads provided in a top surface of the substrate;
inserting the substrate into a space between the first leads and the second leads such that the first leads slide onto the first solder on the first pads; and
forming a second solder on a plurality of second pads provided in a back surface of the substrate,
wherein each of the first pads provides a cut opened for an insertion direction of the substrate, the cut having a left oblique edge and a right oblique edge with a space narrowing along the insertion direction, and
wherein each of the first leads is aligned with the first pads by the cut at the insertion of the substrate.

11. The method of claim 10,
wherein each of the second leads is aligned with the second pads during the insertion of the substrate by visual inspection.

12. The method of claim 10,
wherein each of the second pads provides the cut, each of the second leads being aligned by the cut during the insertion of the substrate without visual inspection.

13. A method to assemble an optical module with an optical cable, the optical module including a substrate for mounting electronic components and optical components thereon, and an electronic connector having a plurality of first leads and a plurality of second leads, the method comprising steps of:
forming a first solder on a plurality of first pads provided in a top surface of the substrate, each of the first pads providing a cut formed by a left oblique edge and a right oblique with a space gradually narrowing along the first pads;
forming a second solder on a plurality of second pads provided in a back surface of the substrate, each of the second pads providing a cur formed by a left oblique edge and a right oblique edge with a space gradually narrowing along the second pads;
inserting the substrate into a space between the first leads and the second leads such that the first leads slide onto the first solder on the first pads and the second leads slide onto the second solder on the second pads; and
soldering the first solder and the second solder to fix the first leads and the second leads to the substrate,
wherein each of the first leads and each of the second leads are aligned with the first pads and the second pads, respectively, at the insertion of the substrate.
